(19) United States
(12) Patent Application Publication
(10) Pub. No.: US 2012/0087087 A1
(43) Pub. Date: Apr. 12, 2012

(54) Method And Device For Controlling An Air Conditioning System For Data Processing Facilities

(75) Inventors: Michael Nicolai, Allertshausen (DE); Martin Doerrich, Mittenaar (DE); Tim Siegel, Houston, TX (US); Helmut Saal, Soerth (DE)

(73) Assignee: RITTAL GMBH & CO., KG, Herborn (DE)

(21) Appl. No.: 13/138,507

(22) PCT Filed: Mar. 1, 2010
(86) PCT No.: PCT/EP2010/052559

§ 371 Date: Dec. 9, 2011

(30) Foreign Application Priority Data
Mar. 2, 2009 (DE) 10 2009 011 007.0

(51) Int. Cl. H05K 7/20

(52) U.S. Cl. 361/679.48; 361/679.46

(57) ABSTRACT

The invention relates to a method for controlling an air conditioning system for a data processing facility that comprises at least one row of server switch cabinets, wherein the row of server switch cabinets bounds a cold aisle that is sealed off from a hot aisle facing away from the cold aisle side, wherein hot air is drawn in, cooled, and blown into the cold aisle by at least one air conditioner, and wherein cold air is drawn out of the cold aisle and fed into the hot aisle or into the surrounding space by at least one of the server switch cabinets. The invention further relates to a corresponding device for performing the method. According to the invention, the control of the air supply rate of the air conditioner is performed by means of a pressure controller, wherein a measured pressure difference between a pressure sensor in the cold aisle or in the hot aisle and a pressure sensor in the surrounding space outside the cold aisle or the hot aisle is used as an input variable of the pressure controller. The device comprises a control unit for performing the method. Using the method and the device, optimal and at the same time energy-saving cooling of such data processing facilities can be provided. In addition, the operational reliability is increased, because failures or defects in the air supply can be detected directly.

The invention relates to a method for controlling an air conditioning system for a data processing facility that comprises at least one row of server switch cabinets, wherein the row of server switch cabinets bounds a cold aisle that is sealed off from a hot aisle facing away from the cold aisle side, wherein hot air is drawn in, cooled and blown into the cold aisle by at least one air conditioner, and wherein cold air is drawn out of the cold aisle and fed into the hot aisle or into the surrounding space by at least one of the server switch cabinets.

The invention further relates to a corresponding device for performing the method.

Normally, data processing facilities consist of a plurality of server switch cabinets into which individual electronic modules (so-called racks) having own fans and cold air intakes and hot air outlets for cooling are installed.

Those server switch cabinets are arranged in several rows and are aligned such that cold air intakes or hot air outlets respectively, of the individual server switch cabinets are opposing each other and corresponding cold aisles and hot aisles are mutually formed between the server switch cabinets. In a double-row arrangement of server switch cabinets normally a cold aisle is formed between the two server switch cabinet rows. Hot air outlets of the server switch cabinets are located at the outside of this arrangement and blow the hot air into the surrounding space.

For air conditioning or in particular for cooling, respectively, of these data processing facilities, different concepts are known from the prior art.

For example, it may be provided that hot air blown out from server switch cabinets is centrally sucked by an air conditioning system, is cooled and the cold air is blown into the cold aisle. To increase efficiency of cooling, the cold aisle is normally sealed off laterally and from the top in relation to the hot aisles or the surrounding space, respectively. Documents WO 03/083631 and U.S. Pat. No. 6,859,366 B2, for example, describe arrangements of this type.

In view of a particular effective air conditioning of such arrangement, so-called inline air-conditioners have proven which are arranged between the server switch cabinets in specific spacings, dependent on the power-loss of the data processing facility which must be dissipated. These air conditioners comprise fans which suck hot air from the hot aisles or from surrounding air via hot air intakes, cool by means of one or several heat exchangers through which water/cooling agent flows and blow in via cold air in-blows into the sealed off cold aisles.

Corresponding air-conditioners are for example mentioned in product catalogue “RITTAL Handbuch 32/IT-Solutions”, pages 726 ff., as well as in information brochure “RITTAL IT-Cooling Solutions”, 03/08, under the name of “LCP Inline”. LCP means Liquid Cooling Package and describes air conditioners which may be placed within data processing facilities between server switch cabinets and comprise heat exchangers with water cooling.

With regard of optimized computer performance as well as in view of operating reliability, it is required that on the input side supply air having a specific maximum air temperature is offered to the racks in the server switch cabinets. If this temperature is achieved or even exceeded, lifetime of the installed components is drastically reduced, involving high service costs. Therefore, it is required that inflow of cold air is adapted to the needs of the individually operating racks at all times. Presently, a temperature controlled regulation of fan performance is used. If delta T on the airside is increased, fan performance is increased. However, it has turned out that such a regulation involves disadvantages due to comparatively slow response of the regulation, for example when defects occur suddenly or when cold air needs increase rapidly.

Therefore, it is the object of the invention to provide a controlling method which ensures an improved supply with cold air meeting the demands and increases efficiency of the air conditioning system.

The object concerning the method is solved by performing control of the air supply rate of the air conditioner by means of a pressure controller, wherein a measured pressure difference between a pressure sensor in the cold aisle or in the hot aisle and a pressure sensor in the surrounding space outside the cold aisle or the hot aisle is used as an input variable of the pressure controller.

The object concerning the device is solved in that the air conditioner comprises a control unit or is in communication with a superordinate control unit, which on the input side communicates with at least one pressure sensor and at least one second pressure sensor and on the output side with one or more fans of the air conditioner, wherein by means of the measured pressure difference between the pressure sensor which is arranged in the cold aisle or in the hot aisle, and the pressure sensor which is arranged in the unbound space outside the cold aisle or the hot aisle, a signal for controlling the fan rotation can be derived.

Using the method and the device, optimal and at the same time energy-saving cooling of such data processing facilities can be provided. Compared to the prior art, air flow is offered in the amount as sucked from the individual server switch cabinets as cold air. This control meeting the demands assists in saving energy costs and especially also to increase lifetime of the fans, since these can always be operated in optimal operating range. On the other hand, operating security is increased, since pressure variations due to the failure of one or several fans or disorders of air supply manifest immediately and may therefore be detected by said device. Compared to an air conditioning system controlled by temperature, this system offers the advantage of an extremely short response time.

In the method according to the invention it is provided that for overpressure exceeding a maximum difference pressure default value, air supply volume of the air conditioner or air conditioners is reduced in the cold aisle, and for underpressure underrunning a minimum difference pressure default value in the cold aisle, the air supply volume of the air conditioner is increased.

Thereby it can be provided that the air supply volume of the air conditioner is varied by variation of the number of revolutions of a fan associated to the air conditioner. This may for example be realized by a corresponding proportional control of the fan revolution.

In a design variant of the facility, it is also conceivable that the surrounding space is formed by the hot aisle. In principle, such a method may be provided for a sealed off cold aisle in which the differential pressure between cold aisle and the unbound region of the space is used for controlling the fan performance. However, also conceivable is a sealed off hot aisle which collects hot air blown in from the server switch cabinets which air is then sucked off by means of the air conditioner, cooled and on the input side provided to the server switch cabinet as cold air. The control method as previously described as well as the corresponding device may be used also here.

Thereby, the pressure difference between the sealed off cold aisle or hot aisle and the surrounding space outside is controlled to be within a specific pressure difference range, wherein the pressure in the cold aisle is correspondingly increased in relation to the surrounding space or the pressure in the hot aisle is correspondingly decreased in relation to the surrounding space. Thereby it is ensured that on the one hand, sufficient cold air or a small excess of cold air is offered to the cold aisle for supplying the server switch cabinets, and, on the other hand, from a sealed off hot aisle, sufficient hot air is sucked off so that heat cannot build up.

In case of a sudden overrun or underrun of this pressure difference range, an optical and/or acoustic alarm signal and/or an alarm message may be issued to a superordinate monitoring facility of the data processing facility. Failure or partial failure of fan performance may therefore be detected very quickly. Further, fan revolution or volume flow of still intact fans can be increased correspondingly, to ensure sufficient cooling of the server switch cabinets.

But also gradual pressure drops or pressure rises, respectively, may be detected, which may be indicative of gradual loss of supply of volume flow, for example due to clogged air filters or bearing wear.

A particularly precise control and detection of disorders may be achieved, if control is performed to a pressure difference range between 5 and 30 Pa.

In a preferred method variant, two or more pressure sensors in the cold aisle or in the hot aisle and/or two or more pressure sensors in the surrounding space are used for pressure determination. This offers the advantage that redundancy is present should a pressure sensor deliver faulty measurement values.

On the other hand, the evaluation with respect to pressure variations can be configured in terms of operational stability if a respective average value is calculated from the measured values of the pressure sensors in the sealed off cold aisle or hot aisle and from the measured values of pressure sensors outside the boundaries, and a differential pressure is determined using these average values for a relevant pressure.

If the pressure sensors are arranged in the bound region as well as in the region outside the boundaries and outside a direct flow of a cold air flow and/or and a hot air flow, it can be ensured that in particular for this fine control no falsification of measurement results due to additional underpressure as a result of air flow and/or accumulation overpressure may occur. This could in particular deliver faulty measured values if for example the pressure sensors are directly arranged in front of outlet or intake regions of the fans of the server switch cabinets or the air conditioners.

A particular beneficial device variant is achieved when the pressure sensors in the sealed off region and outside the sealed off region are configured as differential pressure sensor.

On the one hand, the labour required for installation is reduced, since only one sensor is to be connected. Moreover, a mutual monitoring of both partial sensors can be realized, since both partial sensors correspond directly with signal processing and are therefore able to generate a signal to the control unit immediately, if for example one of the two partial sensors delivers faulty values.

To increase the operational security of such facilities, it is provided that the air conditioner is connected to an optical and/or acoustic warning unit and/or to a superordinate monitoring facility of the data processing facility on its outlet side. Thus, failure of a fan may be indicated by an optical or acoustic, respectively, alarm or, if for example the pre-adjusted pressure control range is permanently exceeded, a corresponding warning is generated at a control room.

In a beneficial embodiment of the device it comprises further features which are required to perform the method as previously described. These are for example corresponding comparators and differential amplifiers, power controllers or revolution controllers, respectively, for the fan motors as well as electronic components for signal processing of measuring signals from the pressure sensor. In addition, monitoring facilities for monitoring the pressure sensors as well as plausibility monitorings to avoid false alarms may be provided.

The invention will be explained further below by means of an exemplary embodiment illustrated in the figures. It is shown in:

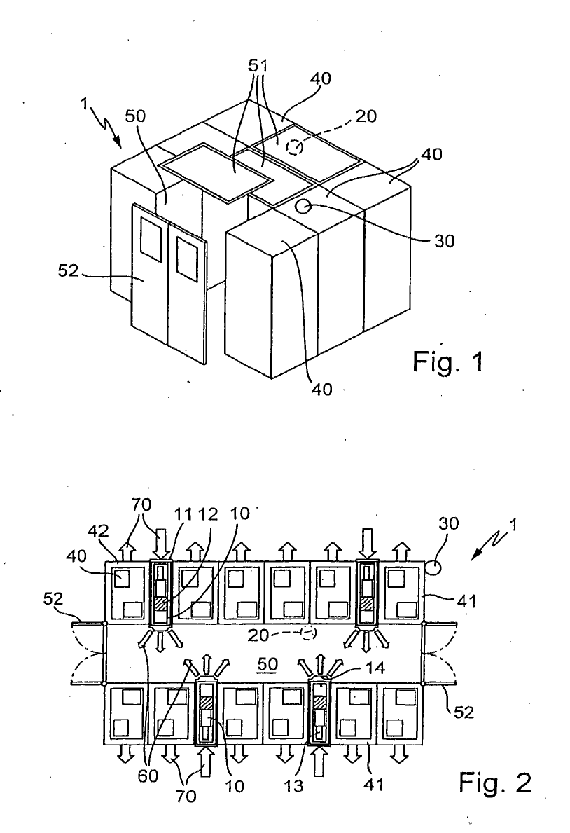

FIG. 1 a data processing facility, consisting of two rows of server switch cabinets in a perspective representation,

FIG. 2 a layout of a data processing facility comprising server switch cabinets and several air conditioners, and

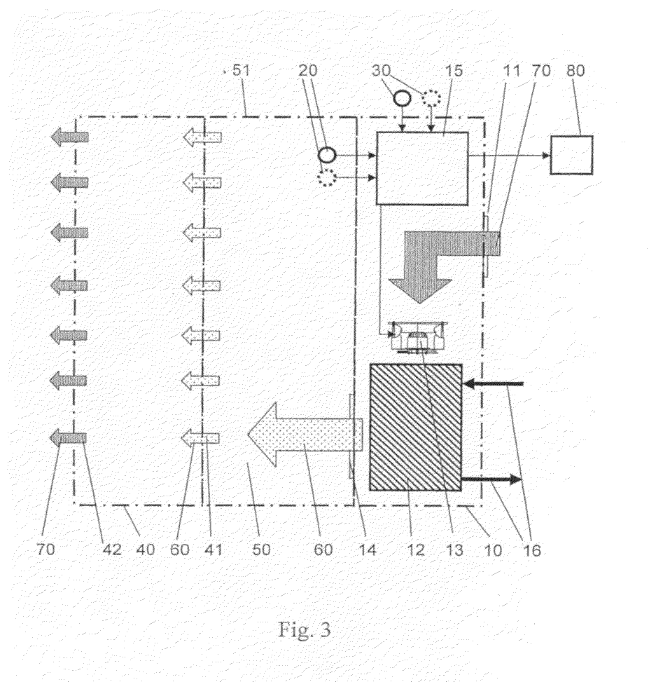

FIG. 3 in a schematic representation a control unit for performing the control method according to the invention.

FIG. 1 shows part of a data processing facility 1 mentioned in the introductory which is composed of several server switch cabinets 40. Server switch cabinets 40 are normally arranged in two rows spaced from another, so that a cold aisle 50 is formed. Cold aisle 50 is sealed off against the surrounding space with plates for top separation 51 and door separations 52. An air conditioner 10 is provided for cooling which is placed between server switch cabinets 40 and which draws in hot air from the surrounding space outside, cools it and blows it into cold aisle 50 as cold air. Each of the server switch cabinets possesses a plurality of system modules having individual fans operating independently from another which draw in cold air in cold aisle 50. Air heated by power loss is then passed to the space surrounding data processing facility 1.

It is worth noting here that the method according to the invention and the corresponding device also relates to a server switch cabinet assembly which consists only of one row of server switch cabinets and forms a cold aisle or a hot aisle with a wall opposing cold air intakes or hot air intakes of the server switch cabinets and which are sealed of against the surrounding space by means of separations.

FIG. 2 shows a layout of a data processing facility 1 with several server switch cabinets 40 and several air conditioners 10 arranged between server switch cabinets 40 as they are for example known under the name of “LCP Inline” of the applicant.

Server switch cabinets 40 are arranged in two rows, wherein a cold aisle 50 is formed between the rows which is approximately hermetically sealed off against the surrounding space by means of door separations 52 and top separations 51 (not visible in this view). By means of air conditioners 10, hot air is drawn in from the surrounding space by means of fans 13 via a hot air intake and cooled by means of heat exchangers 12. Thereby, cooling water is passed through heat exchangers 12. Thus, cooled air is supplied to cold aisle 50 as cold air via cold air blow-ins 14.

Server switch cabinets 40 possess cold air intakes 41 at the face facing cold aisle 50, so that cold air can be individually, corresponding to installed system components and current need of cold air, drawn in from cold aisle 50. Air heated by power loss is supplied back to the space surrounding data processing facility 1 by means of hot air outlets 42.

Several shaded arrows symbolize a corresponding cold air and hot air flow 60, 70.

According to the invention, at least one pressure sensor 20 is provided in cold aisle 50 and another pressure sensor 30 outside the sealed off cold aisle 50 in this arrangement which are connected to a control unit 15, not represented here, for signalling. This control unit 15 may be a component of each air conditioner 10 or component of a superordinate monitoring facility.

FIG. 3 shows schematically the device according to the invention for performing the method according to the invention. A schematic cross section of the data processing facility 1 illustrated in FIG. 2 is represented.

An air conditioner and a server switch cabinet 40 are shown which are oppositely arranged separated by cold aisle 50. Cold aisle 50 is nearly hermetically sealed off at the top with a top separation 51 and laterally with door separations 52 (not visible in this view).

Cold air and hot air flows 60, 70 are illustrated as block arrows in this figure. Hot air is drawn in from the surrounding space via hot air intake 11 of air conditioner 10 by means of one or several fans 13, wherein normally air filters are provided on the input side, which, however, are not shown here. Subsequently, hot air is passed through heat exchanger 12, wherein the air is cooled. In the example as shown, heat exchanger 12 possesses a cooling water circuit 16 which allows to take away heat released from the air. Also possible are cooling circuits which are passed by a cooling agent or a cooling brine. Cold air is then supplied to cold aisle 50 via cold air blow-in 14.

Data processing components (racks) installed in server switch cabinets 40 draw in cold air via corresponding cold air intakes 41. Heated air then flows through corresponding hot air outlets 42 opposing cold air intakes 41 into the space surrounding the assembly.

According to the invention a control unit 15 is provided for air volume control which in the example as shown is a component of air conditioner 10. On the input side, one or several pressure sensors 20 are connected thereto which are located in the interior of cold aisle 50 and are preferably mounted at zones of weak flow to avoid faulty measures due to strong flow or dynamic pressure. Outside of sealed off cold aisle 50 further pressure sensors 30 are mounted which are also located at places of weak flow. On the outlet side, control unit 15 is connected to fan(s) 13.

Moreover, on the outlet side of control unit 15 is in the example as shown a warning means 80 (e.g. warning light, horn and/or superordinate monitoring facility) is associated with control unit 15 which is connected to control unit 15 for signalling.

If air conditioners 10 convey more air volume flow than taken from server equipment in server switch cabinets 40 or needed, respectively, overpressure builds up in cold aisle 50. This pressure difference is detected with the aid of several pressure sensors 20, 30 and evaluated in control unit 15. Depending on the result, fan revolution of fans 13 in air conditioners 10 is reduced.

If, on the other hand, air conditioners 10 convey less air volume flow than currently needed by server equipment, negative pressure occurs in cold aisle 50. Thus, fan revolution of fans 13 is increased. Thereby, the pressure difference between the sealed off cold aisle and the surrounding space outside is controlled to a specific pressure difference range (typically 5 to 30 Pa), wherein the pressure in the cold air is maintained correspondingly increased in relation to the surrounding space.

Upon failure of a fan 13, pressure in cold aisle 50 decreases immediately below the said pressure difference range, so that still functional fans 13 in air conditioners 10 or still functional air conditioners 10, respectively, may immediately increase fan revolution or volume flow, respectively.

Simultaneously, a warning signal to the warning means 80 and/or superordinate monitoring facility may be generated.

With the aid of the method and the device, it may be achieved that on the one hand an optimal and simultaneously energy saving cooling of such data processing facilities 1 is provided. On the other hand, operational security is increased, since failures or defects of air flow may be detected immediately.

1-14. (canceled)

15. A method for controlling an air conditioning system for a data processing facility that comprises at least one row of server switch cabinets, wherein the row of server switch cabinets bounds a cold aisle that is sealed off from a hot aisle facing away from the cold aisle's side, wherein hot air is drawn in, cooled and blown into the cold aisle by at least one air conditioner placed between said server switch cabinets and wherein cold air is drawn out of the cold aisle and fed into the hot aisle or into the surrounding space by at least one of the server switch cabinets, wherein the control of the air supply rate of the air conditioner is performed by means of a pressure controller, wherein a measured pressure difference between a pressure sensor in the cold aisle or in the hot aisle and a pressure sensor in the surrounding space outside the cold aisle or the hot aisle is used as an input variable for the pressure controller.

16. The method of claim 15, wherein for an overpressure exceeding a maximum difference pressure default value in said cold aisle the air supply rate of said air conditioner is reduced and for a negative pressure underrunning a minimum difference pressure default value in said cold aisle, the air supply rate of said air conditioner is increased.

17. The method of claim 15, wherein the air supply rate of said air conditioner is varied by variation of the number of revolutions of a fan associated with said air conditioner.

18. The method of claim 15, wherein the pressure difference between the sealed off cold aisle or hot aisle and the surrounding space outside is controlled to a specific difference, wherein the pressure in said cold aisle is correspondingly increased in relation to the surrounding space or the pressure in said hot aisle is correspondingly maintained decreased in relation to the surrounding space.

19. The method of claim 18, wherein at sudden overrun or underrun of this pressure difference range an optical and/or an acoustic warning signal and/or a warning message is issued to a superordinate monitoring facility of said data processing facility.

20. The method of claim 16, wherein controlling is performed to achieve a pressure difference range between 5 and 30 Pa.

21. The method of claim 15, wherein two or more pressure sensors in said cold aisle or in said hot aisle and/or two or more pressure sensors in said surrounding space are used for pressure determination.

22. The method of claim 21, wherein an average value is calculated from the measured values of said pressure sensors in said cold aisle or in said hot aisle and the measured values of said pressure sensors in said surrounding space, respectively, and a difference pressure is determined with the aid of these average values for the pressure.

23. A device for controlling an air conditioning system for a data processing facility that comprises at least one row of server switch cabinets wherein the row of server switch cabinets bounds a cold aisle which is sealed off from a hot aisle facing away from the cold aisle's side, wherein hot air is drawn in, cooled and blown into the cold aisle by at least one air conditioner placed between said server switch cabinets and wherein cold air is drawn out of the cold aisle and fed into the hot aisle or into the surrounding space by at least one of the server switch cabinets, wherein said air conditioner comprises a control unit or is connected to a superordinate control unit which on the input side is connected to at least one pressure sensor in said cold aisle or in said hot aisle and at least one second pressure sensor in said surrounding space and on the outlet side with one or several fans of said air conditioner, wherein by means of the measured pressure difference between said pressure sensor which is located in said cold aisle or in said hot aisle, and said pressure sensor which is located in said space outside said cold aisle and said hot aisle and is not sealed off, a signal for controlling the fan revolution is derivable.

24. The device of claim 23, wherein said pressure sensor in said cold aisle or in said hot aisle and said pressure sensor in said surrounding space are arranged outside a direct flow of a cold air flow and/or a hot air flow.

25. The device of claim 23, wherein said pressure sensor in said cold aisle or in said hot aisle and said pressure sensor in said surrounding space are configured as differential pressure sensors.

26. The device of claim 23, wherein said air conditioner is on its outlet side connected to an optical and/or acoustic warning means and/or with a superordinate monitoring facility of said data processing facility.

27. The device of claim 23, wherein said surrounding space is formed by said hot aisle.

28. The device of claim 23, utilized to control an air conditioning system for a data processing facility that comprises at least one row of server switch cabinets, wherein the row of server switch cabinets bounds a cold aisle that is sealed off from a hot aisle facing away from the cold aisle's side, wherein hot air is drawn in, cooled and blown into the cold aisle by at least one air conditioner placed between said server switch cabinets and wherein cold air is drawn out of the cold aisle and fed into the hot aisle or into the surrounding space by at least one of the server switch cabinets, wherein the control of the air supply rate of the air conditioner is performed by means of a pressure controller, wherein a measured pressure difference between a pressure sensor in the cold aisle or in the hot aisle and a pressure sensor in the surrounding space outside the cold aisle or the hot aisle is used as an input variable for the pressure controller.
